(19) United States
(12) Patent Application Publication
(10) Pub. No.: US 2023/0140738 A1
(43) Pub. Date: May 4, 2023

(54) MICROELECTRONIC TEST AND PACKAGE INTERFACE SUBSTRATES, DEVICES, AND METHODS OF MANUFACTURE THEREOF ALIGNMENT IMPROVEMENT OF INTERCONNECT ON BUILDUP REDISTRIBUTION LAYERS

(71) Applicant: Raymond Won Bae, Danville, CA (US)

(72) Inventor: Raymond Won Bae, Danville, CA (US)

(21) Appl. No.: 17/515,400

(22) Filed: Oct. 30, 2021

(51) Int. Cl. H01L 23/498; H05K 3/46; H05K 3/40

(52) U.S. Cl. CPC H01L 23/49822; H01L 23/49894; H01L 23/49827; H05K 3/4644; H05K 3/4038

(57) ABSTRACT

An embodiment of the present invention provides a method and system of manufacturing a redistribution platform comprising and providing a substrate; buildup layer level by registry measurement, calculation, and adjustment; the first layer registry validation for the 2^{nd} layer to each consequent buildup; top layer builds up to validate the registration to interconnection with the test probe assembly system or the semiconductor device.

### TECHNICAL FIELD

An embodiment of the present invention relates generally to microelectronic buildup redistribution layer system.

### BACKGROUND

The interface substrate and device designs are increasingly become more complex in terms of layer counts and circuit density. The current method of test and package interface substrate manufacturing thereof involves mechanical and/or laser drilling, and heat lamination processes to stack up multi-layers cause misalignment of conductor X and Y coordinate registry between inner layers and top layer. Hence it creates the not only the low yield in production with the increase in the delivery lead-time but decrease in reliability with the increase in the cost. And they become a major component in the semi-conductor and electronic testing and packaging industry. Modern consumer and industrial electronics, cellular phones, mobile devices, and computing systems, are providing increasing levels of volume production to require more and more faster, flexible, and reliable test and package interface substrate to meet the market demands. Research and development in the existing technologies can take a myriad of different directions.

As users become more empowered with the growth of computing devices, new and old paradigms begin to take advantage of this new device space. There are many technological solutions to take advantage of this new device capability and device miniaturization. However, reliable fabrication and faster delivery of wafers through new devices has become a concern for manufactures.

Thus, a need still remains for a microelectronic buildup redistribution layer system for testing and packaging of wafers and devices. In view of the ever-increasing commercial competitive pressures, along with growing consumer expectations and the diminishing opportunities for meaningful product differentiation in the marketplace, it is increasingly critical that answers be found to these problems. Additionally, the need to provide with manufacturing capabilities of redistribution system layer to layer levels of reliable buildup process to reduce the lead-time, reduce costs by increasing yields, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### SUMMARY

An embodiment of the present invention provides a microelectronic buildup redistribution layer system, including: a base carrier substrate; conductor traces and a dielectric structure on the substrate, including a plurality of multi-layers.

An embodiment of the present invention provides a method of manufacture thereof controlling the layer-to-layer conductor and pad alignment with other interconnection of test or package platform for semiconductor chips and devices. This improves functional validity, increasing yield, reducing the lead-time and reduce the scraps due to defects in interface substrates. Microelectronic buildup redistribution layer system including: providing a base carrier substrate; forming a plurality of multi-layers on the substrate, conductor traces, conductor vias and a dielectric structure on the substrate.

Certain embodiments of the invention have other steps or elements in addition to or in place of those mentioned above. The steps or elements will become apparent to those skilled in the art from a reading of the following detailed description when taken with reference to the accompanying drawings.

### BRIEF DESCRIPTION OF THE DRAWINGS

FIG. 1 is a schematic side view of a probe card system in an embodiment of the present invention microelectronics test interface redistribution layer system 300 is integrated.

FIG. 2 schematic view of an embodiment of microelectronic test interface substrate system with bottom base carrier substrate view and microelectronic buildup redistribution top layer view with conductor traces and test pads.

FIG. 3 is a schematic cross-sectional side view of an embodiment of microelectronic test interface substrate system 700 traces along line 10-10 in FIG. 2

FIG. 4 is a schematic cross-sectional side view of an embodiment of microelectronic test interface base carrier substrate 500 along line 11-11 in FIG. 2.

FIG. 5 is a schematic Top view of an embodiment of microelectronic test interface base carrier substrate and top view of an embodiment of 1^{st} buildup redistribution layer X and Y coordinate registries.

FIG. 6 is a schematic cross-sectional side view of an embodiment of microelectronic test interface substrate system with base carrier substrate and 1^{st} microelectronic buildup redistribution layer conductor traces.

FIG. 7 is a schematic top view of an embodiment of microelectronic test interface substrate system with base carrier substrate and 1^{st} microelectronic buildup redistribution layer, and cross-sectional side view of line 12-12.

FIG. 8 is a schematic top view of an embodiment of microelectronic test interface 1^{st} buildup redistribution layer and top view of an embodiment of 2^{nd} buildup redistribution layer X and Y coordinate registries.

FIG. 9 is a schematic cross-sectional side view of an embodiment of microelectronic test interface substrate system with base carrier substrate and 1^{st} and 2^{nd} buildup redistribution conductor layers.

FIG. 10 is a schematic top view of an embodiment of microelectronic test interface substrate system with base carrier substrate and 1^{st} microelectronic buildup redistribution layer, 2^{nd} microelectronic buildup redistribution layer and cross-sectional side view of line 13-13.

FIG. 11 is a schematic cross-sectional side view of an embodiment of microelectronic test interface substrate system with base carrier substrate and 1^{st,} 2^{nd}, and 3^{rd} buildup redistribution conductor layers.

FIG. 12 is a schematic top view of an embodiment of microelectronic test interface substrate system with base carrier substrate and 2^{nd} microelectronic buildup redistribution layer, 3^{rd} microelectronic buildup redistribution layer and cross-sectional side view of line 14-14.

FIG. 13 is a schematic cross-sectional side view of an embodiment of microelectronic test interface substrate system with base carrier substrate and 1^{st,} 2^{nd,} 3^{rd}, and 4^{th} buildup redistribution conductor layers.

FIG. 14 is a schematic cross-sectional side view of an embodiment of microelectronic test interface substrate system with base carrier substrate and 1^{st,} 2^{nd,} 3^{rd,} 4^{th}, and 5th redistribution conductor buildup layers.

FIG. 15 is schematic Top layer view and side view of X and Y registry coordinate on top 5^{th} microelectronic buildup redistribution layer for interconnect probe head assembly system 620 in FIG. 1, and cross-sectional side view of line 15-15.

FIG. 16 is a schematic cross-sectional side view of an embodiment of microelectronic test interface substrate system with base carrier substrate and 1^{st ,} 2^{nd}, 3^{rd} 4^{th}, and top buildup redistribution conductor layers with test pads 110 and side view of alignment for interconnect probe head assembly system 620 in FIG. 1.

### DETAILED DESCRIPTION

The following embodiments are described in sufficient detail to enable those skilled in the art to make and use the invention. It is to be understood that other embodiments would be evident based on the present disclosure, and that system, process, or mechanical changes may be made without departing from the scope of an embodiment of the present invention.

In the following description, numerous specific details are given to provide a thorough understanding of the invention. However, it will be apparent that the invention may be practiced without these specific details. In order to avoid obscuring an embodiment of the present invention, some well-known circuits, system configurations, and process steps are not disclosed in detail.

The drawings showing embodiments of the system are semi-diagrammatic, and not to scale and, particularly, some of the dimensions are for the clarity of presentation and are shown exaggerated in the drawing figures. Similarly, although the views in the drawings for ease of description generally show similar orientations, this depiction in the figures is arbitrary for the most part. Generally, the invention can be operated in any orientation.

The registry alignment process showing embodiments of the system are shown only the 1^{st} distribution layer to the base carrier substrate, 2^{nd} distribution layer to 1^{st} distribution layer, and the top layer registration to probe head. However, multiple layers can be done through the same buildup redistribution process. The variety of X and Y coordinates and registry method can be used depend on the substrate size, shapes and point references, and they are openly available in many design and image tools.

The registry alignment process showing embodiments of the system are shown only the single substrate. However, multiple substrates on the panel can be done through the same buildup redistribution process. The variety of X and Y coordinates and registry method can be used depend on the substrate size, shapes and point references, and they are openly available in many design and image tools.

The designation and usage of the term first, second, third, etc. is for convenience and clarity and is not meant limit a particular order. The steps or processes described can be performed in any order to implement the claimed subject matter.

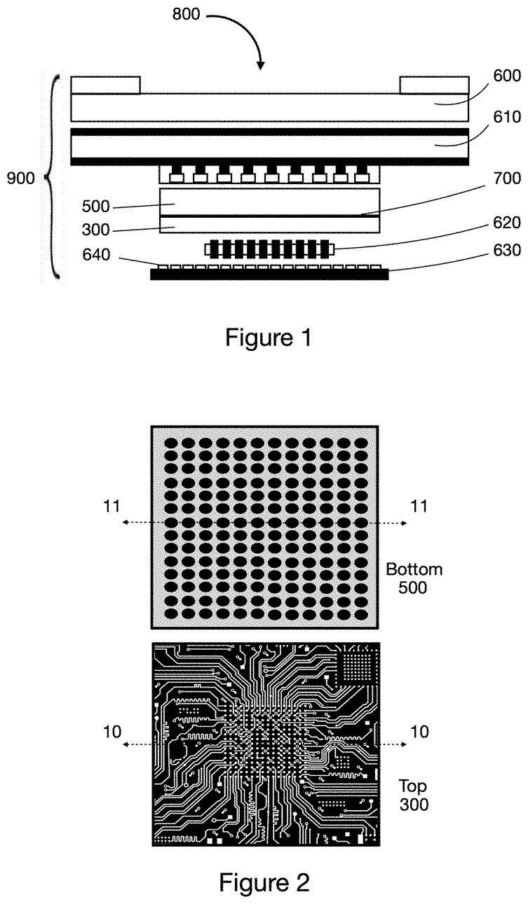

Referring now to FIG. 1, therein is shown an embodiment of microelectronic test interface substrate system schematic side view of a probe card system 800 in an embodiment of the present invention 700 is integrated. The system 800 is a system for providing interconnection between different devices. For example, the system 800 can be a component in a wafer testing system 900 or a substrate in an integrated circuit packaging system. As an example, the wafer testing system 900 can include a mechanical stiffener 600, a printed circuit board 610, a redistribution test interface platform 700 consist of the base carrier substrate 500 and redistribution substrate platform 300, and a probe head 620. The mechanical stiffener 600, the printed circuit board 610, the redistribution test interface platform 700, and the probe head 620 are components for a system to test a semiconductor wafer 630. The semiconductor wafer 630 can include a die 640 with electronic components, such as circuits, integrated circuits, logic, integrated logic, or a combination thereof fabricated thereon.

Referring now to FIG. 2, therein is shown an embodiment of microelectronic test interface substrate system top view of microelectronic buildup redistribution layer 300 of FIG. 1 and bottom view of base carrier substrate 500 of FIG. 1 of the redistribution test interface substrate platform 700. The bottom conductor pads of the test interface substrate are interconnecting toward the printed circuit board 610 of FIG. 1. The top side of the test interface substrates are interconnecting to the probe head 620 of FIG. 1. For wafer chip 630 of FIG. 1 and other logic and integrated devices to be tested.

The redistribution platform 700 is a structure for providing interconnection between two devices. For example, the redistribution platform 700 can be a space transformer, a redistribution structure for a multi-die package, or a combination thereof. The redistribution platform 700 can provide electrical and functional connectivity between semiconductor wafer 630, the die 640, or a combination thereof, and the rest of the redistribution system 800.

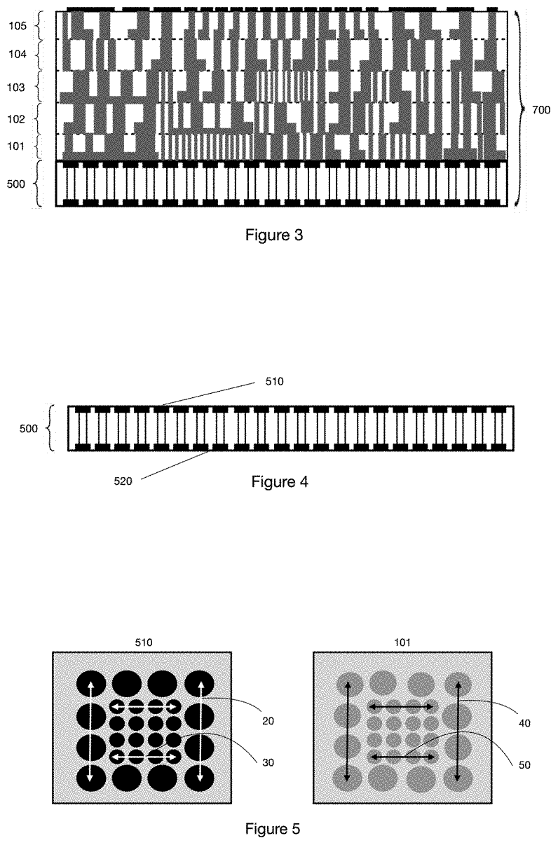

Referring now to FIG. 3, therein is shown an embodiment of microelectronic test interface substrate system cross-sectional side view of the test interface substrate system 700; base carrier substrate 500, the microelectronics redistribution system 300; 1^{st} redistribution layer 101, 2^{nd} redistribution layer 102, 3^{rd} redistribution layer 103, 4^{th} redistribution layer 104 and 1^{st} top distribution layer 105. For illustrative purpose, the redistribution conductor is depicted having a similar shape from the side view, although it is understood that the system 700 can have a different shape and more or less layers than the illustration. For example, the redistribution conductor system in 101, 102, 103, 104 and 105 can have any shapes and thickness to meet the needs of testing and packaging interface design requirement, such as a square, or rectangular shape, a triangular shape, pentagonal shape, or any other polygonal shapes and curves.

For illustrate purpose, the microelectronic redistribution platform 300 consists only of 5 layers 101, 102, 103, 104 and 105. The total test or package interface substrate redistribution layer counts can be more or less.

The microelectronics buildup redistribution system 300 layers can be signal layer, ground layer, plane layer or the combination thereof.

Referring now to FIG. 4, therein is shown an embodiment of microelectronic test interface substrate system cross-sectional side view of the test interface base substrate system 500 of FIG. 1 500 along the cross line 10-10. The platform 510 of base substrate system 500 is where the microelectronic redistribution substrate layers are buildup, and the platform 520 is interconnecting toward the printed circuit board 610 of FIG. 1. For illustrative purpose, the conductor vias are thru hole single layer, although it is understood that system 500 can have a different multi-layer construction.

The platform 500 is a base carrier substrate providing interconnection between redistribution platform 300. For illustrative purposes, the redistribution platform 300 can provide electrical and functional connectivity between the semiconductor wafer, semiconductor dice, or a combination thereof for system testing, such as wafer testing, die testing, package testing, or inter-package testing.

The base carrier substrate 500 can be a rigid foundation or base layer for the redistribution player platform 300. The substrate 500 can include an electrically insulating material, such as a ceramic based or polymer composite based material.

Referring now to FIG. 5, therein is shown an embodiment of microelectronic test interface substrate system top view of base carrier substrate 510 and top view of 1^{st} microelectronic redistribution layer conductor 101. The platform 510 X-coordinates 30 and Y-coordinates 20 are calculated and measured. These calculated and measured coordinates are matched with the 1^{st} microelectronic redistribution layer. For illustrative purposes, interconnecting conductor alignment between the base carrier platform 510 and the 1^{st} microelectronic redistribution layer 101 may require within micron (μm) accuracy.

The 1^{st} microelectronic redistribution platform 101 X-coordinates 50 and Y-coordinates 40 can be matched or adjusted to buildup functionally and mechanically reliable redistribution layer from the base substrate 500.

For example, the collected registration data are used to continually improve the future complexity microelectronic buildup redistribution layer development.

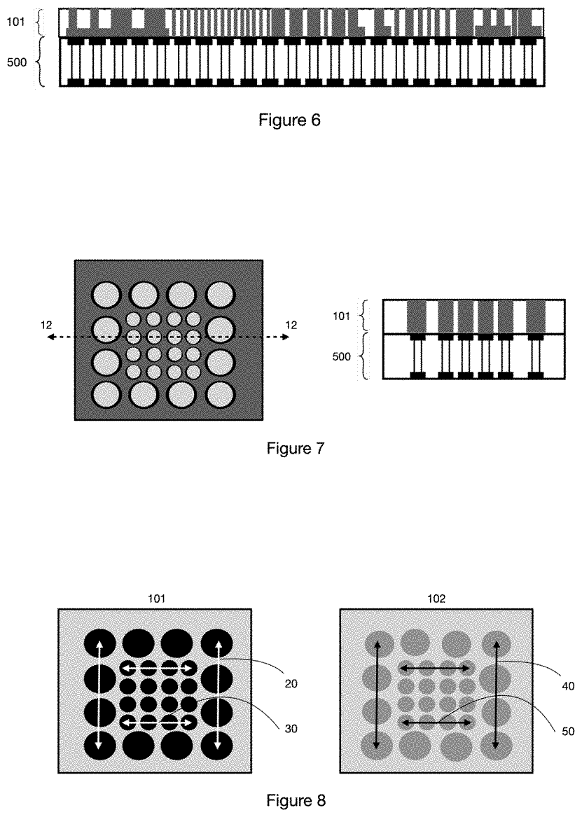

FIG. 6 is an embodiment of microelectronic test interface substrate system schematic cross-sectional side view of an embodiment of microelectronic test interface substrate system with base carrier substrate 500 and 1^{st} microelectronic buildup redistribution layer conductor traces 101.

The platform system can be electronically tested to validate the interconnection of conductors between the base carrier substrate 500 and 1^{st} microelectronic buildup redistribution layer conductor traces 101.

Referring now to FIG. 7 is an embodiment of microelectronic test interface substrate system schematic top view of an embodiment of microelectronic test interface substrate system with base carrier substrate and 1^{st} microelectronic buildup redistribution layer, and cross-sectional side view of line 12-12.

The cross-sectional side view of line 12-12 illustrates the alignment accuracy. This illustrates the ability to calculate X and Y coordinates of the base substrate. It allows to make necessary adjustment to match the microelectronic redistribution layer X and Y coordinates of the subsequent buildup of the redistribution layers.

Referring now to FIG. 8, therein is shown an embodiment of microelectronic test interface substrate system top view of 1^{st} microelectronic buildup redistribution layer 101 and top view of 2^{nd} microelectronic redistribution layer conductor 102. The platform 101 X-coordinates 30 and Y-coordinates 20 are calculated and measured. These calculated and measured coordinates are matched with the 2^{nd} microelectronic redistribution layer. For illustrative purposes, interconnecting conductor alignment between the 1^{st} microelectronic buildup redistribution layer 101 and the 2^{nd} microelectronic redistribution layer 102 may require within micron (μm) accuracy.

The 2^{nd} microelectronic redistribution platform 102 X-coordinates 50 and Y-coordinates 40 can be matched or adjusted to buildup functionally and mechanically reliable redistribution layer from the 1^{st} microelectronic buildup redistribution layer 101.

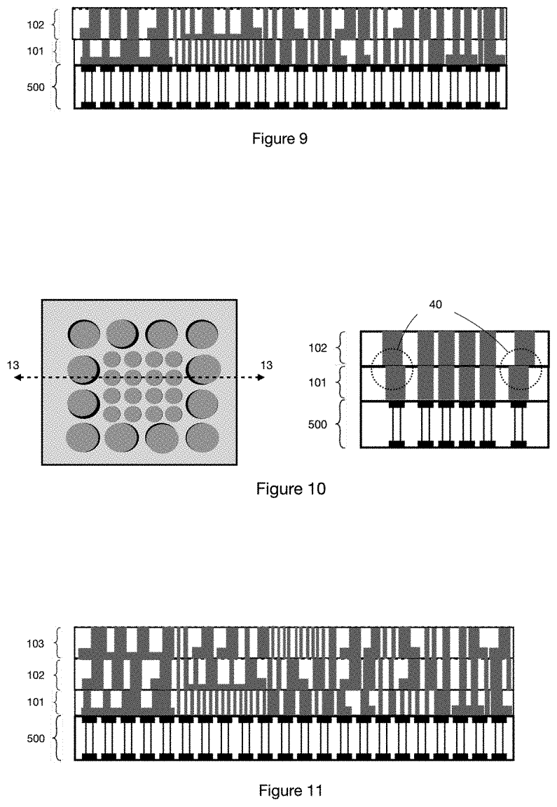

FIG. 9 is a schematic an embodiment of microelectronic test interface substrate system cross-sectional side view of an embodiment of microelectronic test interface substrate base system with 1^{st} microelectronic redistribution buildup layer conductor traces 101 and the 2^{nd} microelectronic redistribution layer 102.

The platform system can be electronically tested to validate the interconnection of conductors between the 1^{st} microelectronic buildup redistribution layer conductor traces 101 and the 2^{nd} microelectronic redistribution layer 102.

Referring now to FIG. 10 is an embodiment of microelectronic test interface substrate system schematic top view of an embodiment of microelectronic test interface substrate system with the 1^{st} microelectronic buildup redistribution layer 101 and the 2^{nd} microelectronic redistribution layer 102, and cross-sectional side view of line 13-13.

The cross-sectional side view of line 13-13 illustrates the alignment accuracy. This illustrates the ability to calculate X and Y coordinates of the base substrate. It allows to make necessary adjustment to match the microelectronic redistribution layer X and Y coordinates of the subsequent buildup of the redistribution layers.

In one embodiment, the cross-sectional side view of line cross 13-13 shows the offset of interconnecting conductors between the 1^{st} and 2^{nd} microelectronic redistribution layers. For illustrative purposes, interconnecting conductors 40 are intentionally offset in design before the microelectronic distribution buildup of 2^{nd} layer for the better alignment of the next subsequent redistribution 3^{rd} layer.

FIG. 11 is an embodiment of microelectronic test interface substrate system schematic cross-sectional side view of an embodiment of microelectronic test interface substrate base system with 1^{st} microelectronic buildup redistribution layer conductor traces 101, the 2^{nd} microelectronic redistribution layer 102 and the 3^{rd} microelectronic redistribution layer 103.

The platform system can be electronically tested to validate the interconnection of conductors between the 1^{st} microelectronic redistribution layer 101, the 2^{nd} microelectronic redistribution layer 102 and 3^{rd} microelectronic redistribution layer 103.

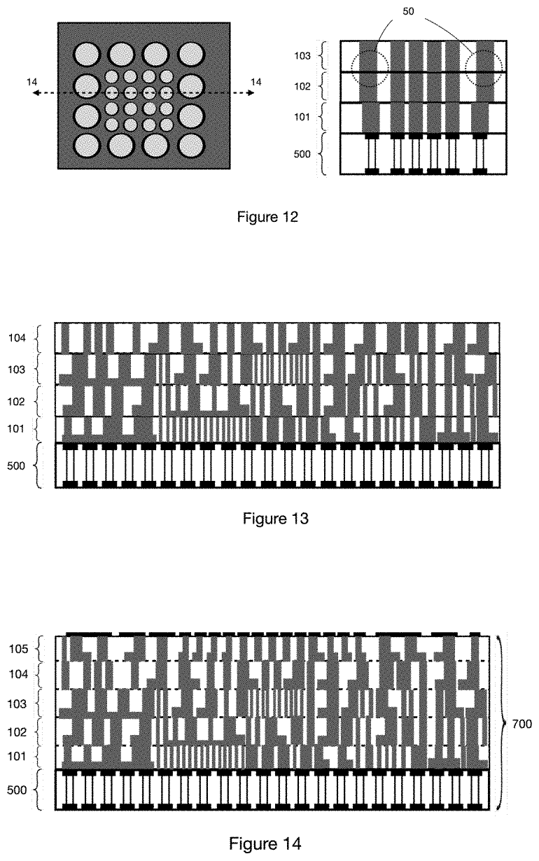

Referring now to FIG. 12 is an embodiment of microelectronic test interface substrate system schematic top view of an embodiment of microelectronic test interface substrate system with the 2^{nd} microelectronic buildup redistribution layer 102 and the 3^{rd} microelectronic redistribution layer 103, and cross-sectional side view of line 14-14.

The cross-sectional side view of line 14-14 illustrates the alignment accuracy. This illustrates the ability to calculate X and Y coordinates of the prior redistribution layer. It also allows to make necessary adjustment of X and Y coordinates of the redistribution layer for the subsequent buildup of the redistribution layers.

In one embodiment, the cross-sectional side view of line cross 14-14 shows the interconnecting conductors between the 2^{nd} and 3^{rd} microelectronic redistribution layers. For illustrative purposes, interconnecting conductors 50 are almost perfectly aligned based on open buildup redistribution layer allows the X and Y coordinate measurement and ability to make the design adjustment for subsequent build up layers.

FIG. 13 is an embodiment of microelectronic test interface substrate system schematic cross-sectional side view of an embodiment of microelectronic test interface substrate base system with 1^{st} microelectronic buildup redistribution layer conductor traces 101, the 2^{nd} microelectronic redistribution layer 102, the 3^{rd} microelectronic redistribution layer 103 and 4^{th} microelectronic redistribution layer 104.

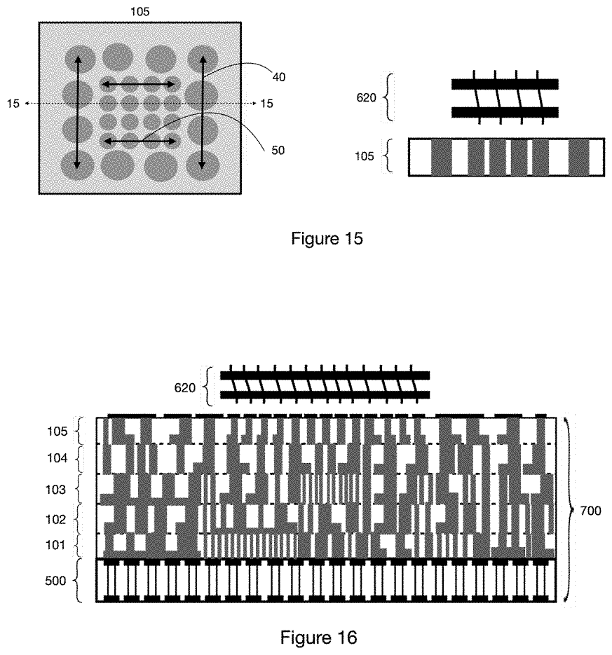

FIG. 14 is an embodiment of microelectronic test interface substrate system schematic cross-sectional side view of an embodiment of microelectronic test interface substrate base system with 1^{st} microelectronic buildup redistribution layer conductor traces 101, the 2^{nd} microelectronic redistribution layer 102 and the 3^{rd} microelectronic redistribution layer, 4^{th} microelectronic redistribution layer 104 and 5^{th} top microelectronic redistribution layer 105.

FIG. 15 is an embodiment of microelectronic test interface substrate system schematic Top layer view and side view of X and Y registry coordinate on top 5^{th} microelectronic buildup redistribution layer with the test pads 110 for interconnect probe head assembly system 620, and cross-sectional side view of line 15-15.

For example, microelectronic redistribution top layer test pads X and Y coordinates are very critical for the interconnection with the probe head assembly 620. The probe head 620 are components for a system to test a semiconductor wafer 630 in FIG. 1.

For illustrative purposes, the probe head assembly test pin counts are increasing and pin to pin pitch is decreasing that the micron level alignment and accuracy are critical for the test interface substrate.

FIG. 16 is an embodiment of microelectronic test interface substrate system schematic cross-sectional side view of an embodiment of microelectronic test interface substrate system with base carrier substrate and 1^{st,} 2^{nd,} 3^{rd,} 4^{th,} 5^{th}, and top buildup redistribution conductor layers with test pads 110 and side view of alignment for interconnect probe head assembly system 620.

The resulting method, process, apparatus, device, product, and/or system is straightforward, cost-effective, uncomplicated, highly versatile, accurate, sensitive, and effective, and can be implemented by adapting known components for ready, efficient, and economical manufacturing, application, and utilization. Another important aspect of an embodiment of the present invention is that it valuably supports and services the historical trend of reducing costs, simplifying systems, and increasing performance.

These and other valuable aspects of an embodiment of the present invention consequently further the state of the technology to at least the next level.

While the invention has been described in conjunction with a specific best mode, it is to be understood that many alternatives, modifications, and variations will be apparent to those skilled in the art in light of a foregoing description. Accordingly, it is intended to embrace all such alternatives, modifications, and variations that fall within the scope of the included claims. All matters set forth herein or shown in the accompanying drawings are to be interpreted in an illustrative and non-limiting sense.

What is claimed is:

1. Microelectronic buildup redistribution layer system comprising; A, a substrate comprising base carrier, dielectric, conductor traces, conductor vias connecting layers. B, a microelectronic redistribution layers include a buildup process on base carrier. C, a microelectronic redistribution layers included the different or same layers.

2. Microelectronic buildup redistribution layer system of claim 1, wherein the via conductor provide an interlocking or connecting function with the top or bottom layer conductor.

3. Microelectronic buildup redistribution layer system of claim 1, wherein the base carrier substrate is a ceramic material in construction of single or multi-layers.

4. Microelectronic buildup redistribution layer system of claim 1, wherein the base carrier substrate is an organic, printed circuit board, material in construction of single or multi-layers.

5. Microelectronic buildup redistribution layer system of claim 1, wherein the base carrier substrate is a wafer.

6. Microelectronic buildup redistribution layer system of claim 1, wherein the base carrier substrate is a glass.

7. Microelectronic buildup redistribution layer system of claim 1, wherein the base carrier substrate is a quartz.

8. Microelectronic buildup redistribution layer system of claim 1, wherein the dielectric is a polyimide-based polymer material.

9. Microelectronic buildup redistribution layer system of claim 1, wherein the dielectric is an epoxy-based polymer material.

10. Microelectronic buildup redistribution layer system of claim 1, wherein the dielectric is a resin-based polymer material.

11. Microelectronic buildup redistribution layer system of claim 1, wherein the base carrier substrate includes a through substrate via in the substrate and connected to the conductor traces.

12. Microelectronic buildup redistribution layer system of claim 1, wherein the substrate is a polymer composite substrate.

13. A method of manufacturing microelectronic buildup redistribution layer system comprising and providing a substrate; A, forming a plurality of microelectronic redistribution layers on the substrate, the redistributions layers including a dielectric layer and conductive (conductor) traces. B, forming a multi-layer structure by cross-linking or connecting layers by via conductor.

14. The method of claim 13, wherein forming the microelectronic redistribution layers includes the polymer layer as a polyimide-based polymer material.

15. The method of claim 13, wherein forming the redistribution layers includes the polymer layer as an epoxy-based polymer material.

16. The method of claim 13, wherein providing the substrate includes providing the substrate including a through substrate vias and forming the redistribution layers include the conductive traces connected to the through substrate via.

17. The method of claim 13, wherein providing the substrate includes providing a ceramic substrate.

18. The method of claim 13, wherein providing the substrate includes providing a polymer composite substrate.

19. The method of claim 13, wherein providing the substrate includes providing many base materials.

20. The method of claim 13, wherein proving the substrate includes providing no lamination process for the multi-layered redistribution system.

21. The method of claim 13, wherein proving the substrate includes layer to layer buildup process for the multi-layered redistribution system.

22. The method of claim 13, wherein proving the substrate includes layer level X and Y coordinate measurement, calculation, and adjustment on buildup process for the multi-layered redistribution system.
